(19) United States
(12) Patent Application Publication
(10) Pub. No.: US 2022/0170478 A1
(43) Pub. Date: Jun. 2, 2022

(54) Micro Water Pump and Electronic Device Using Same

(71) Applicant: AAC Microtech (Changzhou) Co., Ltd., Changzhou City (CN)

(72) Inventor: Detao Xu, Shenzhen (CN)

(21) Appl. No.: 17/533,154

(22) Filed: Nov. 23, 2021

(30) Foreign Application Priority Data
Nov. 27, 2020 (CN) 202011358653.9

(51) Int. Cl. F04D 29/42; F04D 13/06; F04D 29/08; F04D 29/22

(52) U.S. Cl. CPC F04D 29/426; F04D 13/06; H05K 7/20272; F04D 29/22; F04D 29/086

(57) ABSTRACT

The present invention provides a micro water pump including a pump body provided with an inner cavity, an inlet communicating with the inner cavity, and an outlet communicating with the inner cavity. A drive mechanism is installed on the pump body for driving liquid from the inlet into the inner cavity and discharge from the outlet. The pump body includes a base, an upper cover, and a sealing ring sandwiched between the base and the upper cover. One of the base and the upper cover includes a first circular groove surrounding the inner cavity for arranging the sealing ring; and the other of the base and the upper cover includes at least one circular waterproof step embedded in the first circular groove.

### FIELD OF THE PRESENT DISCLOSURE

The present disclosure relates to fluid machinery, in particular to a micro water pump.

### DESCRIPTION OF RELATED ART

A sealing ring is usually sandwiched between a base and an upper cover of a pump body to achieve sealing. The existing sealing ring between the base and the upper cover of the existing water pump has poor sealing effect and is prone to leakage problems.

Therefore, it is necessary to study a new type of micro water pump to solve the above problems.

### SUMMARY OF THE PRESENT INVENTION

One of the objects of the present invention is to provide a micro water pump with improved heat-dissipation performance.

To achieve the above-mentioned objects, the present invention provides a micro water pump, comprising: a pump body provided with an inner cavity, an inlet communicating with the inner cavity, and an outlet communicating with the inner cavity; a drive mechanism installed on the pump body for driving liquid from the inlet into the inner cavity and discharge from the outlet. The pump body comprises a base, an upper cover, and a sealing ring sandwiched between the base and the upper cover. One of the base and the upper cover includes a first circular groove surrounding the inner cavity for arranging the sealing ring; and the other of the base and the upper cover includes at least one circular waterproof step embedded in the first circular groove.

In addition, the sealing ring surrounds an outer circumference of the circular waterproof step.

In addition, the micro water pump further comprises a rotating shaft mounted with the base or upper cover, wherein the drive mechanism comprises an impeller arranged in the inner cavity for being rotatably connected with the rotating shaft, a rotor installed on the impeller, and a stator in the base for driving the rotor to rotate.

In addition, the impeller comprises a circular part, an installation part located inside the circular part and rotationally connected with the rotating shaft, and a blade located on an outer sidewall of the circular part; the rotor is a circular magnet installed in the circular part or the installation part.

In addition, the rotor is fixed to an inner sidewall of the circular part or the outer sidewall of the installation part by gluing.

In addition, a second circular groove is provided on a side of the base back to the upper cover for embedding the stator therein.

In addition, the micro water pump further comprises a circuit board installed on the base and electrically connected to the stator via a cable.

In addition, a side of the base back to the upper cover includes an installation slot for embedding the circuit board therein.

In addition, a side of the base back to the upper cover is provided with a cable groove communicating with the second circular groove and the installation slot, for accommodating the cable.

The present invention further provides an electronic device comprising a liquid-cooled heat dissipation system, having a micro water pump as described above.

### BRIEF DESCRIPTION OF THE DRAWINGS

Many aspects of the exemplary embodiments can be better understood with reference to the following drawings. The components in the drawing are not necessarily drawn to scale, the emphasis instead being placed upon clearly illustrating the principles of the present disclosure.

FIG. 1 is an illustrative isometric view of a micro water pump in accordance with an exemplary embodiment of the present invention;

FIG. 2 is also an illustrative isometric view of a micro water pump in FIG. 1, but from another aspect;

FIG. 3 is a cross-sectional view of the micro water pump in FIG. 1, taken along line AA;

FIG. 4 is an exploded and cross-sectional view of the micro water pump;

FIG. 5 is an exploded and isometric view of the micro water pump;

FIG. 6 is similar to FIG. 5, from another aspect;

FIG. 7 is an isometric view of a rotating shaft of the micro water pump;

FIG. 8 is a cross-sectional view of a micro water pump in accordance with another exemplary embodiment of the present invention;

FIG. 9 is a structural diagram of an electronic device incorporating the micro water pump.

### DETAILED DESCRIPTION OF THE EXEMPLARY EMBODIMENTS

The present disclosure will hereinafter be described in detail with reference to exemplary embodiments. To make the technical problems to be solved, technical solutions and beneficial effects of the present disclosure more apparent, the present disclosure is described in further detail together with the figures and the embodiments. It should be understood the specific embodiments described hereby is only to explain the disclosure, not intended to limit the disclosure.

It should be noted that all directional indicators (such as up, down, left, right, front, back, inside, outside, top, bottom . . . ) in the embodiments of the present invention are only used to explain that they are in a specific posture (As shown in the Fig. below), the relative positional relationship between the components, etc., if the specific posture changes, the directional indication will also change accordingly.

It should also be noted that when an element is referred to as being “fixed on” or “arranged on” another element, the element may be directly on the other element or there may be a centering element at the same time. When an element is referred to as being “connected” to another element, it can be directly connected to the other element or an intermediate element may be present at the same time.

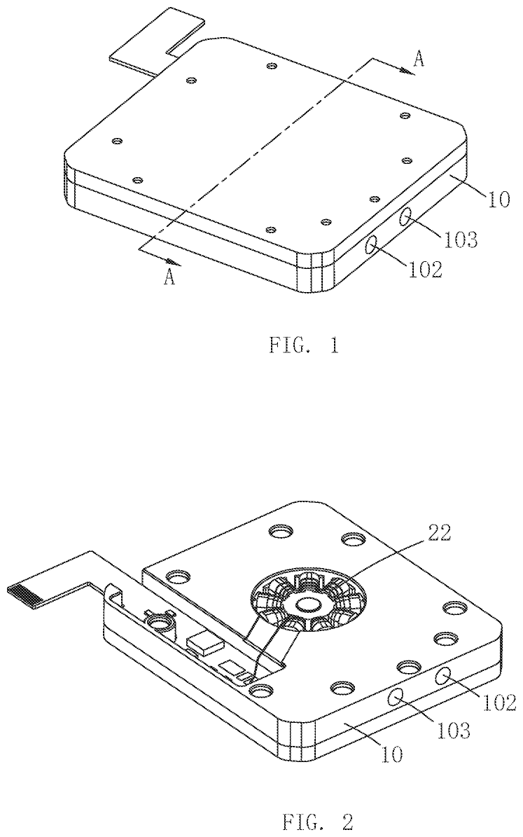

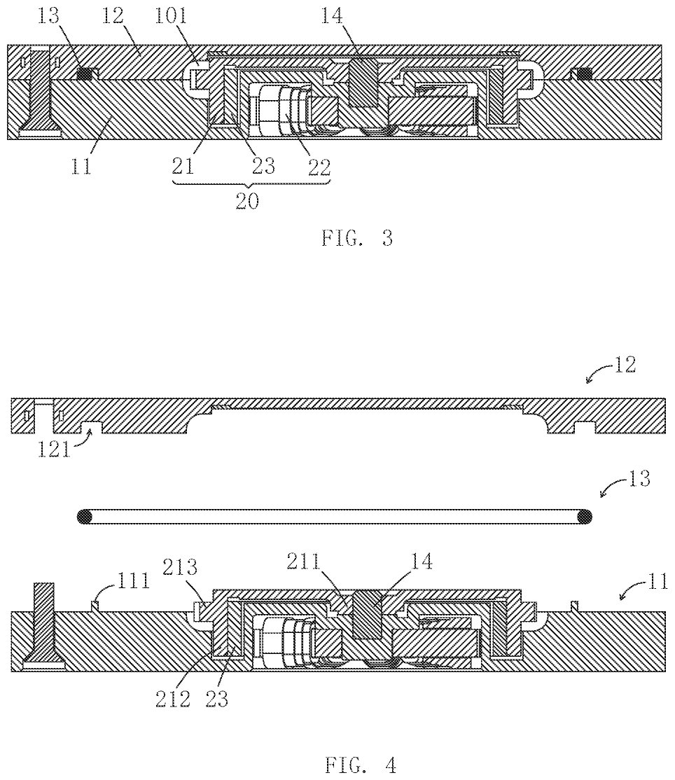

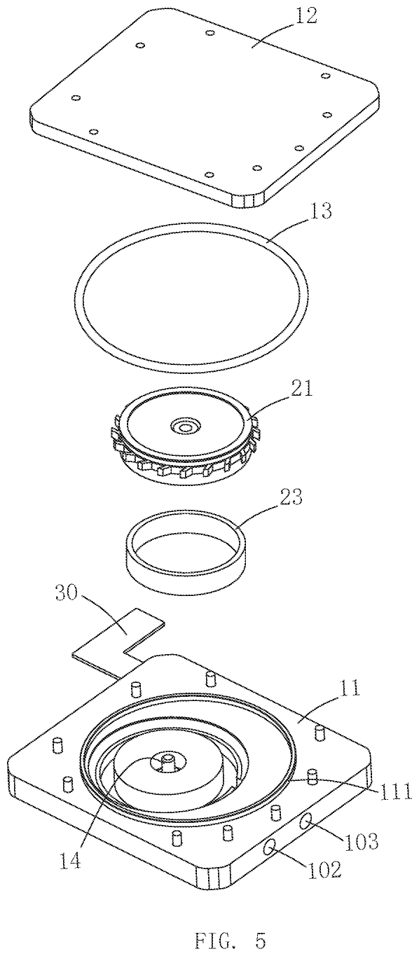

As shown in FIGS. 1-4, an embodiment of the present invention provides a micro water pump comprising a pump body 10 and a drive mechanism 20. The pump body 10 includes an inner cavity 101, an inlet 102 connected to the inner cavity 101, and an outlet 103 connected to the inner cavity 101. The drive mechanism 20 is installed in the pump body 10 to drive liquid from the inlet 102 into the inner cavity 101 and discharged from the outlet 103.

The pump body 10 comprises a base 11, an upper cover 12 and a sealing ring 13. The upper cover 12 includes a first circular groove 121 surrounding the inner cavity 101. The base 11 includes a circular waterproof step 111. The circular waterproof step 111 is embedded in the first circular groove 121. The sealing ring 13 is arranged in the first circular groove 121 and sandwiched between the base 11 and the upper cover 12. When the upper cover 12 is connected to the base 11, the upper cover 12 and the base 11 squeeze the sealing ring to form a seal between the upper cover 12 and the base 11. The liquid in the inner cavity 101 is prevented from leaking out from the gap between the upper cover 12 and the base 11.

It should be noted that the positions of the first circular groove 121 and the circular waterproof step 111 can be interchanged, that is, the first circular groove 121 is set to the base 11, and the circular waterproof step 111 is set to the upper cover 12. It should also be noted that the number of circular waterproof step 111 is not limited to one, and it can also be more than one, depending on actual design requirements.

In this embodiment, one of the base 11 and the upper cover 12 includes a first circular groove 121 surrounding the inner cavity 101. At least one circular waterproof step 111 is provided in the other of base 11 and upper cover 12. The circular waterproof step 111 is embedded in the first circular groove 121. The circular waterproof step 111 can not only increase the water flow resistance, but also reduce the risk of water leakage when the sealing ring 13 is poorly sealed. Moreover, the cooperation of the circular waterproof step 111 and the first circular groove 121 can be used to realize the positioning between the base 11 and the upper cover 12, which facilitates the assembly of the pump body 10.

Optionally, the sealing ring 13 surrounds the outer circumference of the circular waterproof step 111. This design is convenient for the installation of sealing ring 13. During installation, you can first set the sealing ring 13 on the outer circumference of the circular waterproof step 111, and then move the sealing ring 13 and the circular waterproof step 111 into the first circular groove 121 together. the installation is simple. Of course, the sealing ring 13 can also be installed inside the circular waterproof step 111. When multiple circular waterproof steps 111 are arranged, the sealing ring 13 is set on the outer circumference of one of the circular waterproof steps 111.

Exemplarily, both the first circular groove 121 and the circular waterproof step 111 are circular. The first circular groove 121 and the circular waterproof step 111 can also have other shapes, depending on actual design requirements.

Optionally, the circular waterproof step 111 and the base 11 are integrally formed.

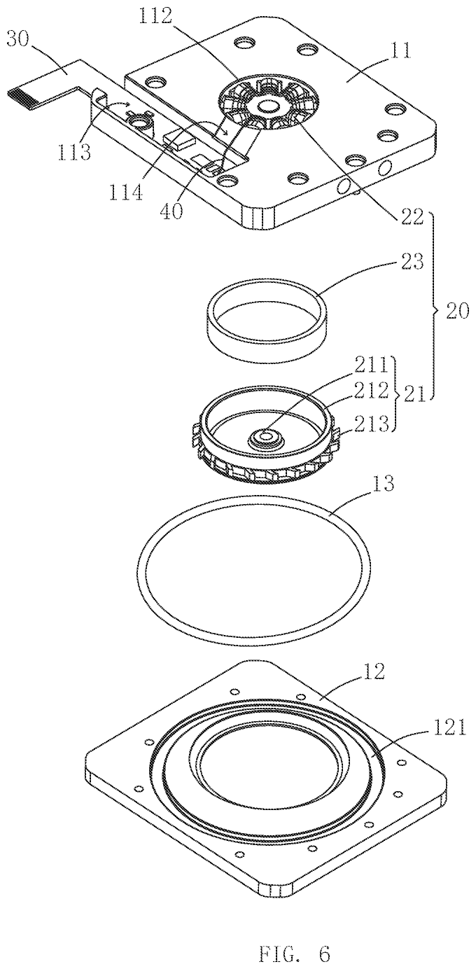

As shown in FIGS. 3-6, the drive mechanism 20 comprises an impeller 21, a stator 22, and a rotor 23. The impeller 21 is located in the inner cavity 101. The base 11 includes a rotating shaft 14. The impeller 21 is connected to the rotating shaft 14 in rotation. The rotor 23 is installed on the impeller 21. The stator 22 is installed in base 11. The stator 22 is used to drive the rotor 23 to rotate.

During operation, alternating current is applied to the stator 22, and according to the principle of electromagnetic induction, the stator 22 generates rotating magnetic field. The rotor 23 is rotated by the ampere force in the rotating magnetic field, and the rotating rotor 23 drives the impeller 21 to rotate. The liquid enters the inner cavity 101 from the inlet 102, rotates at a high speed under the push of the impeller 21 and performs centrifugal motion. When the liquid reaches the outlet 103, it is thrown out from the outlet 103. After the liquid is thrown out, the pressure in the inner cavity 101 decreases, much less than the atmospheric pressure. The external fluid is replenished from the inlet 102 into the inner cavity 101 under the action of atmospheric pressure, and the above-mentioned actions are repeatedly implemented to realize the delivery of the liquid.

The stator 22 and the rotor 23 interact through electromagnetic force, therefore no direct connection therebetween is needed. Thus, no mounting hole communicating with the inner cavity 101 is needed, which can prevent the fluid in the inner cavity 101 from leaking through the mounting hole.

Of course, it is also possible to install a motor in the pump body 10. The output shaft of the motor extends into the inner cavity 101 and is connected to the impeller 21, and the motor drives the impeller 21 to rotate through the output shaft.

The rotating shaft 14 is not limited to being provided in the base 11, and the rotating shaft 14 can also be provided in the upper cover 12.

Optionally, the rotating shaft 14 is molded on the base 11 by over-injection molding. In this embodiment, the connection between the rotating shaft 14 and the base 11 is firm, and the rotating operation of the impeller 21 is stable.

The impeller 21 comprises an installation part 211, a circular part 212 and a blade 213. The installation part 211 is located inside the circular part 212. The installation part 211 is connected to the rotating shaft 14 in rotation. The blade 213 is located on the outer sidewall of the circular part 212. The rotor 23 is a circular magnet installed on the circular part 212. Optionally, the rotor 23 is fixed to the inner sidewall of the circular part 212 by gluing.

Of course, the rotor 23 is not limited to the inner sidewall of the circular part 212 fixed by gluing. For example, the rotor 23 can also be embedded in the circular part 212 by over-injection.

The side of the base 11 opposite to the upper cover 12 includes a second circular groove 112, and the stator 22 is embedded in the second circular groove 112. By setting the second circular groove 112 to accommodate the stator 22, the stator 22 will not increase the overall thickness of the pump body 10, so that the size of the pump body 10 is small.

The micro water pump also comprises a circuit board 30 installed in the base 11, and the circuit board 30 is electrically connected to the stator 22 through a cable 40. An installation slot 113 is provided on the side of base 11 with its back facing the upper cover 12. The circuit board 30 is embedded in the installation slot 113. In this embodiment, the circuit board 30 is accommodated in the installation slot 113 and is not exposed. It is possible to prevent the components on the circuit board 30 from being bumped and damaged in the subsequent installation process. Moreover, the circuit board 30 is accommodated in the installation slot 113, and the circuit board 30 does not increase the overall thickness of the pump body 10, so that the size of the pump body 10 is small. Of course, the base 11 may not be provided with the installation slot 113, and the circuit board 30 is directly installed on the outer surface of the base 11.

A cable groove 114 is provided on the side of the base 11 with its back facing the upper cover 12. The cable groove 114 is connected with the second circular groove 112 and the installation slot 113. The cable 40 is arranged in the cable groove 114. In this embodiment, the cable 40 is wired in the cable groove 114 and is not exposed. It can prevent the cable 40 from being pulled and broken by external forces. Moreover, the cable 40 is wired in the cable groove 114, and the cable 40 does not increase the overall thickness of the pump body 10, so that the size of the pump body 10 is small. Of course, the base 11 may not be provided with the cable groove 114, and the cable 40 is directly wired on the outer surface of the base 11.

As shown in FIG. 7, optionally, the outer sidewall at one end of the connecting shaft 14 and the base 11 includes a concave part 141. When the concave part 141 is used for injection molding of the rotating shaft 14 and the base 11, the base 11 can be partially embedded into the concave part 141, so that the connection between the rotating shaft 14 and the base 11 is stronger. Illustratively, multiple concave parts 141 are arranged, and the multiple concave parts 141 are arranged around the axis of the rotating shaft 14 at intervals.

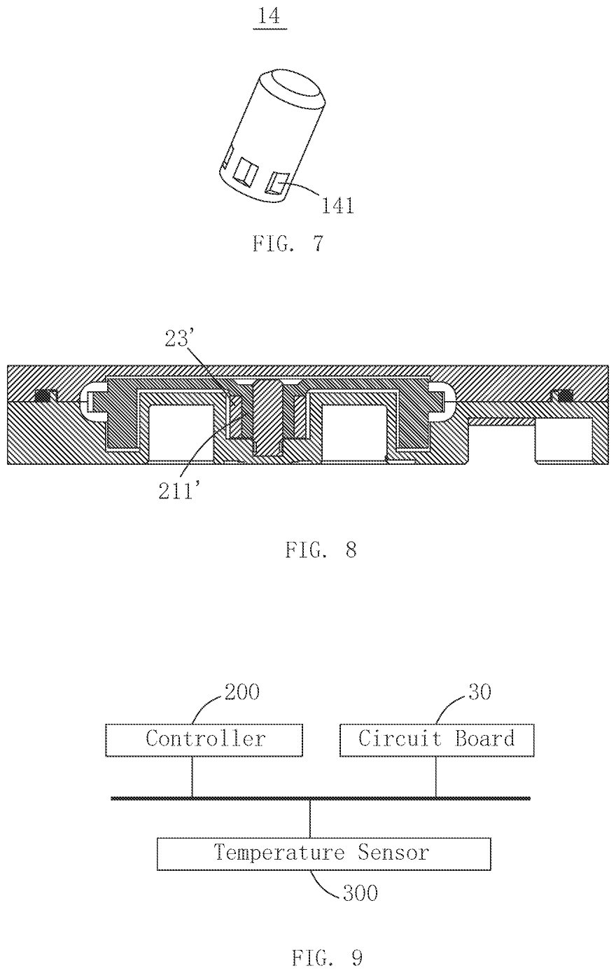

As shown in FIG. 8, the micro water pump proposed in another embodiment of the present invention differs from the micro water pump proposed in the previous embodiment in the following: In this embodiment, the rotor 23′ is installed in the installation part 211′.

Optionally, the rotor 23′ is fixed to the outer sidewall of the installation part 211′ by gluing. Of course, rotor 23′ can also be embedded in installation part 211′ by over-injection. Other components and connection relationships of the micro water pump proposed in this embodiment can refer to the above-mentioned embodiment, and will not be repeated here.

As shown in FIG. 9, an embodiment of the present invention also provides an electronic device comprising a liquid-cooled heat dissipation system, and the liquid-cooled heat dissipation system comprises the above-mentioned micro water pump, which is used to transport coolant.

The electronic device also comprises a controller 200 and a temperature sensor 300, and the temperature sensor 300 and a circuit board 30 are electrically connected to the controller 200. The temperature sensor 300 is installed on the object that needs heat dissipation. The temperature sensor 300 is used to detect the temperature of the object that needs heat dissipation and transmit the detected temperature value to the controller 200. The controller 200 controls the circuit board 30 to adjust the pulse width of the input stator 22 according to the data detected by the temperature sensor 300. Thus, the speed of the impeller 21 is adjusted to change the flow rate of the cooling liquid, so as to achieve a better heat dissipation effect.

It is to be understood, however, that even though numerous characteristics and advantages of the present exemplary embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms where the appended claims are expressed.

What is claimed is:

1. A micro water pump, comprising:
a pump body provided with an inner cavity, an inlet communicating with the inner cavity, and an outlet communicating with the inner cavity;
a drive mechanism installed on the pump body for driving liquid from the inlet into the inner cavity and to discharge from the outlet; wherein
the pump body comprises a base, an upper cover, and a sealing ring sandwiched between the base and the upper cover;
one of the base and the upper cover includes a first circular groove surrounding the inner cavity for arranging the sealing ring; and
the other of the base and the upper cover includes at least one circular waterproof step embedded in the first circular groove.

2. The micro water pump as described in claim 1, wherein the sealing ring surrounds an outer circumference of the circular waterproof step.

3. The micro water pump as described in claim 1 further comprising a rotating shaft mounted with the base or upper cover, wherein the drive mechanism comprises an impeller arranged in the inner cavity for being rotatably connected with the rotating shaft, a rotor installed on the impeller, and a stator in the base for driving the rotor to rotate.

4. The micro water pump as described in claim 3, wherein the impeller comprises a circular part, an installation part located inside the circular part and rotationally connected with the rotating shaft, and a blade located on an outer sidewall of the circular part; the rotor is a circular magnet installed in the circular part or the installation part.

5. The micro water pump as described in claim 4, wherein the rotor is fixed to an inner sidewall of the circular part or the outer sidewall of the installation part by gluing.

6. The micro water pump as described in claim 3, wherein a second circular groove is provided on a side of the base back to the upper cover for embedding the stator therein.

7. The micro water pump as described in claim 6 further comprising a circuit board installed on the base and electrically connected to the stator via a cable.

8. The micro water pump as described in claim 7, wherein a side of the base back to the upper cover includes an installation slot for embedding the circuit board therein.

9. The micro water pump as described in claim 8, wherein a side of the base back to the upper cover is provided with a cable groove communicating with the second circular groove and the installation slot, for accommodating the cable.

10. An electronic device comprising a liquid-cooled heat dissipation system, having a micro water pump as described in claim 1.
